(19) United States
(12) Patent Application Publication
(10) Pub. No.: US 2020/0321502 A1
(43) Pub. Date: Oct. 8, 2020

(54) POWER GENERATION ELEMENT, POWER GENERATION MODULE, POWER GENERATION DEVICE, POWER GENERATION SYSTEM, AND METHOD FOR MANUFACTURING POWER GENERATION ELEMENT

(71) Applicant: KABUSHIKI KAISHA TOSHIBA, Minato-ku (JP)

(72) Inventors: Hisashi YOSHIDA, Kawasaki (JP); Shigeya Kimura, Yokohama (JP)

(73) Assignee: KABUSHIKI KAISHA TOSHIBA, Minato-ku (JP)

(21) Appl. No.: 16/787,287

(22) Filed: Feb. 11, 2020

(30) Foreign Application Priority Data
Apr. 3, 2019 (JP) 2019-071066

(51) Int. Cl. H01L 35/02; H02N 3/00; H02N 11/00; H01J 45/00

(52) U.S. Cl. CPC H01L 35/02; H01J 45/00; H02N 11/002; H02N 3/00

(57) ABSTRACT

According to one embodiment, a power generation element includes first and second conductive layers, and first and second members. The first member is provided between the first and second conductive layers. The first member includes a first crystal region and a first layer region. The first crystal region is between the first layer region and the first conductive layer. An orientation from negative to positive of a polarization of the first crystal region has a component in a first orientation from the first conductive layer toward the second conductive layer. The first layer region includes a first layer-shaped portion spreading along a first surface. The first surface crosses the first orientation. The first layer-shaped portion includes at least one of graphene and a transition metal dichalcogenide. The second member is provided between the first member and the second conductive layer and separated from the first member.

### CROSS-REFERENCE TO RELATED APPLICATIONS

This application is based upon and claims the benefit of priority from Japanese Patent Application No. 2019-071066, filed on Apr. 3, 2019; the entire contents of which are incorporated herein by reference.

### FIELD

Embodiments described herein relate generally to a power generation element, a power generation module, a power generation device, a power generation system, and a method for manufacturing the power generation element.

### BACKGROUND

For example, there is a power generation element that generates power in response to heat from a heat source. It is desirable to stably increase the efficiency of the power generation element.

### BRIEF DESCRIPTION OF THE DRAWINGS

FIG. 1 is a schematic cross-sectional view illustrating a power generation element according to a first embodiment;

FIG. 2 is a schematic cross-sectional view illustrating a power generation element according to a second embodiment;

FIG. 3 is a flowchart illustrating the method for manufacturing the power generation element according to the third embodiment;

FIG. 4 is a flowchart illustrating the method for manufacturing the power generation element according to the third embodiment;

FIG. 5A to FIG. 5F are cross-sectional views illustrating the method for manufacturing the power generation element according to the third embodiment;

FIG. 6 is a flowchart illustrating the method for manufacturing the power generation element according to the third embodiment;

FIG. 7 is a flowchart illustrating the method for manufacturing the power generation element according to the third embodiment;

FIG. 8 is a flowchart illustrating the method for manufacturing the power generation element according to the third embodiment;

FIG. 9A to FIG. 9E are cross-sectional views illustrating the method for manufacturing the power generation element according to the third embodiment;

FIG. 10A and FIG. 10B are schematic cross-sectional views showing a power generation module and a power generation device according to a fourth embodiment; and

FIG. 11A and FIG. 11B are schematic views showing a power generation device and a power generation system according to the embodiment.

### DETAILED DESCRIPTION

According to one embodiment, a power generation element includes a first conductive layer, a second conductive layer, a first member, and a second member. The first member is provided between the first conductive layer and the second conductive layer. The first member includes a first crystal region and a first layer region. The first crystal region is between the first layer region and the first conductive layer. An orientation from negative to positive of a polarization of the first crystal region has a component in a first orientation. The first orientation is from the first conductive layer toward the second conductive layer. The first layer region includes a first layer-shaped portion spreading along a first surface. The first surface crosses the first orientation. The first layer-shaped portion includes at least one selected from the group consisting of graphene and a transition metal dichalcogenide. The second member is provided between the first member and the second conductive layer and separated from the first member.

According to another embodiment, a power generation element includes a first conductive layer, a second conductive layer, a first member, and a second member. The first member is provided between the first conductive layer and the second conductive layer. The first member includes a first crystal region, a first layer region, and a first intermediate region. The first crystal region is between the first layer region and the first conductive layer. An orientation from negative to positive of a polarization of the first crystal region has a component in a first orientation. The first orientation is from the first conductive layer toward the second conductive layer. The first intermediate region is provided between the first layer region and the first crystal region. The first intermediate region includes at least one selected from the group consisting of Li, Na, K, Rb, Cs, Fr, Be, Mg, Ca, Sr, Ba, and Ra. The second member is provided between the first member and the second conductive layer and separated from the first member.

According to another embodiment, a method for manufacturing a power generation element is disclosed. The method can includes forming a first structure body, and causing the first structure body and a second structure body to oppose each other and to be separated from each other. The forming of the first structure body includes forming a first member on a first substrate, forming a first conductive layer on the first crystal region, and removing the first substrate. The first member includes a first layer region and a first crystal region. The first layer region is between the first substrate and the first crystal region. An orientation from negative to positive of a polarization of the first crystal region has a component in an orientation from the first substrate toward the first crystal region. The first layer region includes a first layer-shaped portion. The first layer-shaped portion includes at least one selected from the group consisting of graphene and a transition metal dichalcogenide. The first layer-shaped portion is between the first crystal region and the second structure body in the causing of the first structure body and the second structure body to oppose each other.

According to another embodiment, a method for manufacturing a power generation element is disclosed. The method includes forming a first structure body, and causing the first structure body and a second structure body to oppose each other and to be separated from each other. The forming of the first structure body includes forming a first member on a first substrate, and forming a first conductive layer. The first substrate is conductive. The first member includes a first layer region and a first crystal region. The first crystal region is between the first substrate and the first layer region. An orientation from negative to positive of a polarization of the first crystal region has a component in an orientation from the first substrate toward the first crystal region. The first layer region includes a first layer-shaped portion. The first layer-shaped portion includes at least one selected from the group consisting of graphene and a transition metal dichalcogenide. The first crystal region is between the first conductive layer and the first layer region. The first substrate is between the first conductive layer and the first crystal region. The first layer-shaped portion is between the first crystal region and the second structure body in the causing of the first structure body and the second structure body to oppose each other.

### First Embodiment

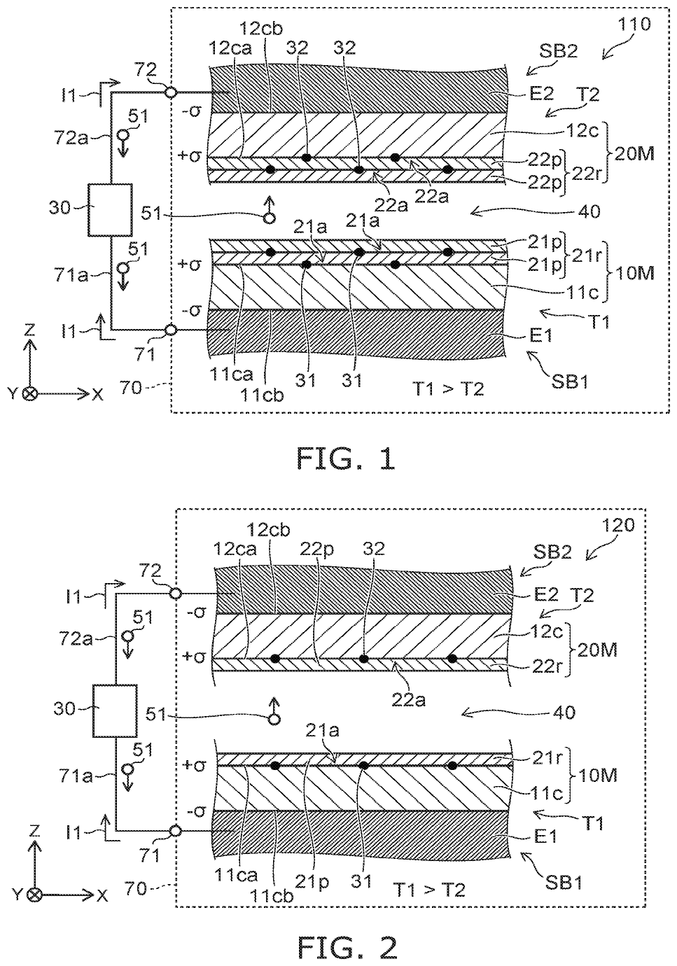

FIG. 1 is a schematic cross-sectional view illustrating a power generation element according to a first embodiment.

As shown in FIG. 1, the power generation element 110 according to the first embodiment includes a first conductive layer E1, a second conductive layer E2, a first member 10M, and a second member 20M.

The first member 10M is provided between the first conductive layer E1 and the second conductive layer E2. The second member 20M is provided between the first member 10M and the second conductive layer E2.

The direction from the first conductive layer E1 toward the second conductive layer E2 is taken as a Z-axis direction. One direction perpendicular to the Z-axis direction is taken as an X-axis direction. A direction perpendicular to the Z-axis direction and the X-axis direction is taken as a Y-axis direction.

In one example, at least a portion of the first conductive layer E1 and at least a portion of the second conductive layer E2 are substantially parallel to the X-Y plane. In one example, at least a portion of the first member 10M and at least a portion of the second member 20M are substantially parallel to the X-Y plane.

The second member 20M is separated from the first member 10M. A gap 40 is provided between the first member 10M and the second member 20M. The gap 40 is in a reduced-pressure state. For example, a container 70 is provided. For example, the first member 10M and the second member 20M are provided in the container 70. The interior of the container 70 is in a reduced-pressure state. Thereby, the gap 40 is in a reduced-pressure state.

For example, the first member 10M is electrically connected to the first conductive layer E1. The second member 20M is electrically connected to the second conductive layer E2. A first terminal 71 and a second terminal 72 are provided. The first terminal 71 is electrically connected to the first conductive layer E1. The second terminal 72 is electrically connected to the second conductive layer E2. A load 30 is electrically connectable between the first terminal 71 and the second terminal 72.

The load 30 is electrically connected to the first conductive layer E1 by first wiring 71a. In the example, the connection is performed via the first terminal 71. The load 30 is electrically connected to the second conductive layer E2 by second wiring 72a. In the example, the connection is performed via the second terminal 72. The power generation element 110 may include the container 70, the first terminal 71, and the second terminal 72. The power generation element 110 may include the first wiring 71a and the second wiring 72a.

The temperature of the first member 10M may be considered to be substantially equal to the temperature of the first conductive layer E1 due to thermal conduction. The temperature of the second member 20M may be considered to be substantially equal to the temperature of the second conductive layer E2 due to thermal conduction.

The temperature of the first conductive layer E1 and the temperature of the first member 10M are taken as a first temperature T1. The temperature of the second conductive layer E2 and the temperature of the second member 20M are taken as a second temperature T2. In one example, the first temperature T1 is set to be higher than the second temperature T2. For example, such a temperature difference can be provided by causing the first conductive layer E1 or the first member 10M to approach or contact a heat source.

In the embodiment, a current I1 flows in the first wiring 71a from the first conductive layer E1 toward the load 30 when such a temperature difference is provided. The current I1 flows in the second wiring 72a from the load 30 toward the second conductive layer E2. The current I1 is the electrical power obtained from the power generation element 110.

It is considered that the current I1 is based on the movement of electrons 51. For example, the electrons 51 are emitted from the first member 10M toward the gap 40. The electrons 51 that move through the gap 40 reach the second member 20M. The electrons 51 flow in the second conductive layer E2 via the second member 20M and reach the load 30 via the second wiring 72a. The electrons 51 flow to the first conductive layer E1 and the first member 10M via the first wiring 71a.

In the embodiment as shown in FIG. 1, the first member 10M includes a first crystal region 11c and a first layer region 21r. The first crystal region 11c is between the first layer region 21r and the first conductive layer E1.

The first crystal region 11c has polarization. The orientation from negative (−σ) toward positive (+σ) of the polarization has a component in a first orientation from the first conductive layer E1 toward the second conductive layer E2.

In one example, the first crystal region 11c has a wurtzite structure. The <000-1> direction of the first crystal region 11c has a component in the first orientation recited above (the first orientation from the first conductive layer E1 toward the second conductive layer E2).

For example, the first crystal region 11c includes a nitride semiconductor. For example, the first crystal region 11c includes AlN. In such a case, a surface 11ca of the first crystal region 11c opposing the first layer region 21r is, for example, substantially the −c plane (the (000-1) plane). A surface 11cb of the first crystal region 11c opposing the first conductive layer E1 is, for example, substantially the +c plane (the (0001) plane).

As shown in FIG. 1, the first layer region 21r includes a first layer-shaped portion 21p. The first layer-shaped portion 21p spreads along a first surface (e.g., the X-Y plane) crossing the first orientation recited above. The first layer-shaped portion 21p includes at least one selected from the group consisting of graphene and a transition metal dichalcogenide. The transition metal dichalcogenide is a compound including a transition metal and a Group 16 element other than oxygen. The transition metal dichalcogenide is represented by the chemical formula MX₂. “M” is a transition metal element. The transition metal element includes, for example, at least one selected from the group consisting of Mo and W. “X” is a Group 16 element other than oxygen. The transition metal dichalcogenide includes, for example, at least one selected from the group consisting of MoS₂ and WS₂. For example, the layer surface of the graphene is substantially along the X-Y plane. The layer surface of the transition metal dichalcogenide is along the X-Y plane.

In the embodiment, the electrons 51 can be emitted efficiently from the first member 10M by using the first crystal region 11c recited above. The efficiency of the power generation can be increased thereby.

There are cases where the front surface of the first crystal region 11c is altered. For example, when the first crystal region 11c is AlN, there are cases where the front surface of the AlN is oxidized; and an oxide film is formed. It was found that changes such as oxidization, etc., occur particularly easily when the front surface of the AlN (the surface from which the electrons 51 are emitted) is the −c plane (the (000-1) plane).

The first layer region 21r recited above is provided in the embodiment. The alteration of the front surface of the first crystal region 11c is suppressed thereby. A power generation element can be provided in which the efficiency can be increased stably thereby.

As shown in FIG. 1, the first layer region 21r may include multiple first layer-shaped portions 21p. One of the multiple first layer-shaped portions 21p is between the first crystal region 11c and another one of the multiple first layer-shaped portions 21p. When one of the first layer-shaped portions 21p is graphene, at least one of the first layer regions 21r is graphite. For example, the alteration of the front surface of the first crystal region 11c is suppressed more stably. For example, the efficiency can be increased more stably.

As shown in FIG. 1, the first member 10M may include a first intermediate region 21a. For example, the first intermediate region 21a is provided between one of the multiple first layer-shaped portions 21p and another one of the multiple first layer-shaped portions 21p. The first intermediate region 21a may be provided between the first layer region 21r and the first crystal region 11c.

In the embodiment, the first intermediate region 21a includes, for example, at least one selected from the group consisting of Li, Na, K, Rb, Cs, Fr, Be, Mg, Ca, Sr, Ba, and Ra (a first element 31). By providing the first intermediate region 21a, for example, the efficiency of the emission of the electrons from the first member 10M increases.

At least one first layer-shaped portion 21p is provided between the first intermediate region 21a and the second member 20M. Thereby, for example, scattering of the first element 31 by becoming separated from the first member 10M can be suppressed. For example, the first element 31 remains easily in the first member 10M. Thereby, a high efficiency is obtained stably due to the first element 31.

As shown in FIG. 1, the first intermediate region 21a may be provided both between one of the multiple first layer-shaped portions 21p and another one of the multiple first layer-shaped portions 21p and between the first layer region 21r and the first crystal region 11c.

The type of the first element 31 included in the first intermediate region 21a provided between the one of the multiple first layer-shaped portions 21p and the other one of the multiple first layer-shaped portions 21p and the type of the first element 31 included in the first intermediate region 21a provided between the first layer region 21r and the first crystal region 11c may be different from each other.

In one example, the first layer-shaped portion 21p includes graphene. The first intermediate region 21a includes Cs.

In the embodiment, the first crystal region 11c may include at least one selected from the group consisting of BaTiO₃, PbTiO₃, Pb(Zrₓ, Ti₁₋ₓ)O₃, KNbO₃, LiNbO₃, LiTaO₃, NaₓWO₃, Zn₂O₃, Ba₂NaNb₅O₅, Pb₂KNb₅O₁₅, and Li₂B₄O₇.

In the example as shown in FIG. 1, the second member 20M includes a second crystal region 12c and a second layer region 22r. The second crystal region 12c is between the second layer region 22r and the second conductive layer E2.

The orientation from negative (−σ) toward positive (+σ) of the polarization of the second crystal region 12c has a component in a second orientation from the second conductive layer E2 toward the first conductive layer E1.

For example, the second crystal region 12c has a wurtzite structure. The <000-1> direction of the second crystal region 12c has a component in the second orientation recited above (the second orientation from the second conductive layer E2 toward the first conductive layer E1).

For example, the second crystal region 12c includes a nitride semiconductor. For example, the second crystal region 12c includes AlN. In such a case, a surface 12ca of the second crystal region 12c opposing the second layer region 22r is, for example, substantially the −c plane (the (000-1) plane). A surface 12cb of the second crystal region 12c opposing the second conductive layer E2 is, for example, substantially the +c plane (the (0001) plane).

For example, the second layer region 22r includes a second layer-shaped portion 22p. The second layer-shaped portion 22p spreads along a second surface (e.g., the X-Y plane) crossing the second orientation recited above. The second layer-shaped portion 22p includes at least one selected from the group consisting of graphene and a transition metal dichalcogenide. The transition metal is a compound including a Group 16 element other than oxygen. The transition metal dichalcogenide is represented by the chemical formula MX₂. “M” is a transition metal element. The transition metal element includes, for example, at least one selected from the group consisting of Mo and W. “X” is a Group 16 element other than oxygen. The transition metal dichalcogenide includes, for example, at least one selected from the group consisting of MoS₂ and WS₂. For example, the layer surface of the graphene is substantially along the X-Y plane. The layer surface of the transition metal dichalcogenide is along the X-Y plane.

By using the second crystal region 12c recited above, the electrons 51 that are emitted from the second member 20M efficiently enter the second member 20M. For example, the efficiency of the power generation can be increased. By providing the second layer region 22r recited above, for example, the alteration of the front surface of the second crystal region 12c is suppressed. For example, a power generation element can be provided in which the efficiency can be increased more stably.

The configuration of the second member 20M may be similar to the configuration of the first member 10M. Thereby, a power generation element in which the efficiency can be increased stably can be manufactured with high productivity.

As shown in FIG. 1, the second layer region 22r may include multiple second layer-shaped portions 22p. One of the multiple second layer-shaped portions 22p is between the second crystal region 12c and another one of the multiple second layer-shaped portions 22p.

As shown in FIG. 1, the second member 20M may further include a second intermediate region 22a. For example, the second intermediate region 22a is provided between the one of the multiple second layer-shaped portions 22p and the other one of the multiple second layer-shaped portions 22p. The second intermediate region 22a may be provided between the second layer region 22r and the second crystal region 12c. The second intermediate region includes at least one selected from the group consisting of Li, Na, K, Rb, Cs, Fr, Be, Mg, Ca, Sr, Ba, and Ra (a second element 32).

By providing the second intermediate region 22a, for example, the efficiency of the electrons entering the second member 20M increases. For example, by setting the configuration of the second member 20M to be similar to the configuration of the first member 10M, a power generation element in which the efficiency can be increased stably can be manufactured with high productivity.

At least one second layer-shaped portion 22p is provided between the second intermediate region 22a and the first member 10M. Thereby, for example, scattering of the second element 32 by becoming separated from the second member 20M can be suppressed. For example, the second element 32 remains easily in the second member 20M. Thereby, a high efficiency is obtained stably due to the second element 32.

As shown in FIG. 1, the second intermediate region 22a may be provided both between one of the multiple second layer-shaped portions 22p and another one of the multiple second layer-shaped portions 22p and between the second layer region 22r and the second crystal region 12c.

The type of the second element 32 included in the second intermediate region 22a provided between the one of the multiple second layer-shaped portions 22p and the other one of the multiple second layer-shaped portions 22p and the type of the second element 32 included in the second intermediate region 22a provided between the second layer region 22r and the second crystal region 12c may be different from each other.

In one example, the second layer-shaped portion 22p includes graphene. The second intermediate region 22a includes Cs.

In the embodiment, the second crystal region 12c may include at least one selected from the group consisting of BaTiO₃, PbTiO₃, Pb(Zrₓ, Ti₁₋ₓ)O₃, KNbO₃, LiNbO₃, LiTaO₃, NaₓWO₃, Zn₂O₃, Ba₂NaNb₅O₅, Pb₂KNb₅O₁₅, and Li₂B₄O₇.

### Second Embodiment

FIG. 2 is a schematic cross-sectional view illustrating a power generation element according to a second embodiment.

As shown in FIG. 2, the power generation element 120 according to the second embodiment includes the first conductive layer E1, the second conductive layer E2, the first member 10M, and the second member 20M. The first member 10M is provided between the first conductive layer E1 and the second conductive layer E2. The first member 10M includes the first crystal region 11c, the first layer region 21r, and the first intermediate region 21a. The first crystal region 11c is between the first layer region 21r and the first conductive layer E1. The orientation from negative (−σ) toward positive (+σ) of the polarization of the first crystal region 11c has a component in the first orientation from the first conductive layer E1 toward the second conductive layer E2.

The first intermediate region 21a is provided between the first layer region 21r and the first crystal region 11c. The first intermediate region 21a includes at least one selected from the group consisting of Li, Na, K, Rb, Cs, Fr, Be, Mg, Ca, Sr, Ba, and Ra (the first element 31).

The second member 20M is provided between the first member 10M and the second conductive layer E2. The second member 20M is separated from the first member 10M.

In the second embodiment as well, for example, the efficiency of the emission of the electrons from the first member 10M is increased by providing the first intermediate region 21a including the first element 31.

At least a portion of the first layer region 21r is provided between the first intermediate region 21a and the second member 20M (referring to FIG. 2). Thereby, for example, the scattering of the first element 31 by becoming separated from the first member 10M can be suppressed. For example, the first element 31 remains easily in the first member 10M. Thereby, a high efficiency is obtained stably due to the first element 31.

As shown in FIG. 2, the first layer region 21r may include the first layer-shaped portion 21p. The first layer-shaped portion 21p spreads along the first surface (e.g., the X-Y plane) crossing the first orientation. The first layer-shaped portion 21p includes, for example, at least one selected from the group consisting of graphene and a transition metal dichalcogenide. The transition metal dichalcogenide is a compound including a transition metal and a Group 16 element other than oxygen. The transition metal dichalcogenide is represented by the chemical formula MX₂. “M” is a transition metal element. The transition metal element includes, for example, at least one selected from the group consisting of Mo and W. “X” is a Group 16 element other than oxygen. The transition metal dichalcogenide includes, for example, at least one selected from the group consisting of MoS₂ and WS₂. For example, the layer surface of the graphene is substantially along the X-Y plane. The layer surface of the transition metal dichalcogenide is along the X-Y plane.

At least a portion of the configuration described in reference to the second member 20M in the first embodiment is applicable to the second embodiment.

As shown in FIG. 1 and FIG. 2, a first structure body SB1 includes at least the first member 10M in the first embodiment and the second embodiment. A second structure body SB2 includes at least the second member 20M. The first structure body SB1 may further include the first conductive layer E1. The second structure body SB2 may further include the second conductive layer E2.

In the first embodiment and the second embodiment, the thickness along the Z-axis direction of at least one of the first crystal region 11c or the second crystal region 12c is, for example, not less than 1 nm and not more than 3000 nm. The thickness along the Z-axis direction of at least one of the first layer region 21r or the second layer region 22r is, for example, not less than 0.3 nm and not more than 30 nm. The length in the Z-axis direction of the gap 40 is, for example, not less than 0.1 μm and not more than 50 μm.

### Third Embodiment

A third embodiment relates to a method for manufacturing a power generation element.

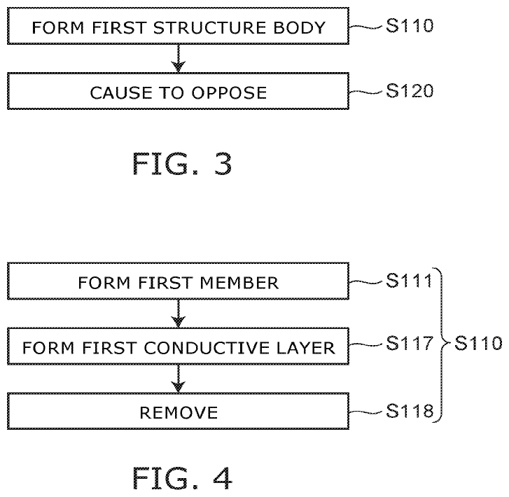

FIG. 3 is a flowchart illustrating the method for manufacturing the power generation element according to the third embodiment. As shown in FIG. 3, the method for manufacturing the power generation element according to the embodiment includes forming the first structure body SB1 (step S110). The manufacturing method includes causing the first structure body SB1 and the second structure body SB2 to oppose each other and to be separated from each other (step S120). The manufacturing method may further include preparing the second structure body SB2. The preparing of the second structure body SB2 may include forming the second structure body SB2. Step S120 may include fixing the first structure body SB1 and the second structure body SB2 to each other in the state in which the first structure body SB1 and the second structure body SB2 oppose each other and are separated from each other.

Several examples of step S110 will now be described.

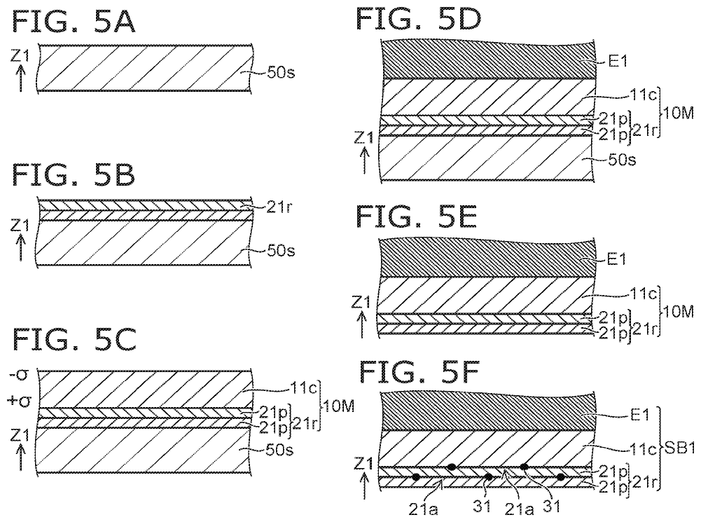

FIG. 4 is a flowchart illustrating the method for manufacturing the power generation element according to the third embodiment. FIG. 5A to FIG. 5F are cross-sectional views illustrating the method for manufacturing the power generation element according to the third embodiment.

In the example shown in FIG. 4, the forming of the first structure body SB1 (step S110) includes forming the first member 10M (step S111), forming the first conductive layer E1 (step S117), and removing the first substrate (step S118).

For example, a first substrate 50s is prepared as shown in FIG. 5A. The first substrate 50s is, for example, a SiC substrate.

As shown in FIG. 5B, the first layer region 21r is formed on the first substrate 50s. For example, the first layer region 21r is formed by changing (e.g., thermal decomposition) a portion of the first substrate 50s by heating. In the example, the first layer region 21r includes graphene (or graphite). The first layer region 21r includes, for example, the first layer-shaped portion 21p.

As shown in FIG. 5C, the first crystal region 11c is formed on the first layer region 21r. A crystal of AlN that is used to form the first crystal region 11c is grown.

Thus, in step S111, for example, the first member 10M that includes the first layer region 21r and the first crystal region 11c is formed on the first substrate 50s (referring to FIG. 5C). The first layer region 21r is between the first substrate 50s and the first crystal region 11c.

As shown in FIG. 5C, for example, the orientation from positive (+σ) toward negative (−σ) of the polarization of the first crystal region 11c has a component in the orientation (e.g., a Z1-direction) from the first substrate 50s toward the first crystal region 11c. The first layer region 21r includes the first layer-shaped portion 21p. The first layer-shaped portion 21p includes at least one selected from the group consisting of graphene and a transition metal dichalcogenide.

In step S117 as shown in FIG. 5D, the first conductive layer E1 is formed on the first crystal region 11c. For example, the first conductive layer E1 is formed by vapor deposition.

In step S118 as shown in FIG. 5E, the first substrate 50s is removed. The first structure body SB1 is formed thereby.

In the example, for example, after the process of FIG. 5E recited above, the first element 31 recited above is introduced to the first layer region 21r. For example, the introduction of the first element 31 is performed by vapor deposition of the first element 31 at reduced pressure. In one example, for example, the first intermediate region 21a that includes the first element 31 is provided between the multiple first layer-shaped portions 21p (referring to FIG. 5F).

As shown in FIG. 5F, for example, the first intermediate region 21a that includes the first element 31 may be provided between the first layer region 21r and the first crystal region 11c.

The second structure body SB2 is prepared separately. The second structure body SB2 may be formed by a method similar to the method for manufacturing the first structure body SB1.

In step S120 recited above (causing the opposing), the first layer-shaped portion 21p is between the first crystal region 11c and the second structure body SB2 (referring to FIG. 1).

For example, the first element 31 recited above may be introduced to the first layer region 21r between the process of FIG. 5B recited above and the process of FIG. 5C.

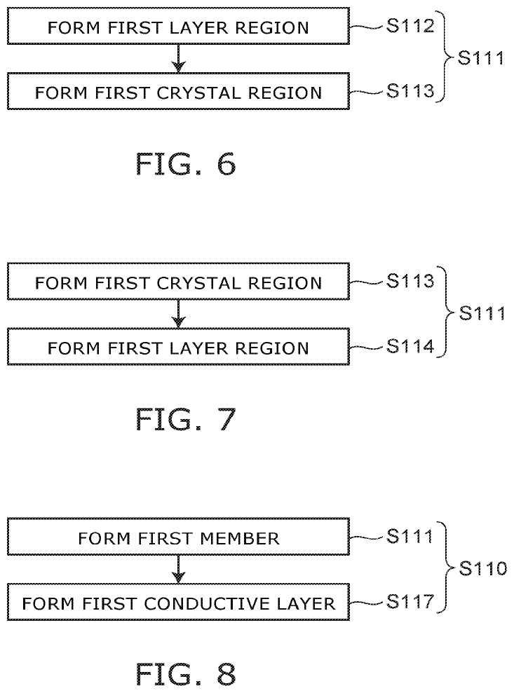

FIG. 6 and FIG. 7 are flowcharts illustrating the method for manufacturing the power generation element according to the third embodiment.

As shown in FIG. 6, the forming of the first member 10M (step S111) may include forming the first layer region 21r (e.g., AlN) on the first substrate 50s (step S112) and forming the first crystal region 11c on the first layer region 21r (step S113).

As shown in FIG. 7, the forming of the first member 10M (step S111) may include forming the first crystal region 11c (e.g., AlN) on the first substrate 50s (step S113) and forming the first layer region 21r from a portion of the first substrate 50s by performing heat treatment after forming the first crystal region 11c (step S114).

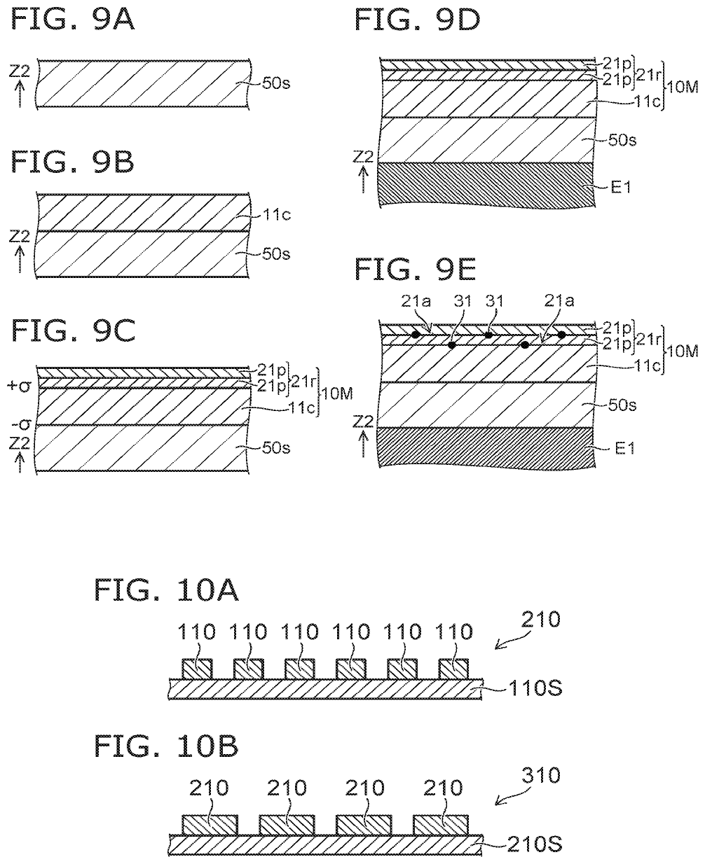

FIG. 8 is a flowchart illustrating the method for manufacturing the power generation element according to the third embodiment. FIG. 9A to FIG. 9E are cross-sectional views illustrating the method for manufacturing the power generation element according to the third embodiment.

In the example as well, as described in reference to FIG. 3, the manufacturing method includes forming the first structure body SB1 (step S110) and causing the first structure body SB1 and the second structure body SB2 to oppose each other and to be separated from each other (step S120). As shown in FIG. 8, the forming of the first structure body SB1 (step S110) includes forming the first member 10M (step S111) and forming the first conductive layer E1 (step S117).

For example, the first substrate 50s is prepared as shown in FIG. 9A. The first substrate 50s is, for example, a SiC substrate. The first substrate 50s is conductive.

As shown in FIG. 9B, the first crystal region 11c is formed on the first substrate 50s. For example, AlN that is used to form the first crystal region 11c is formed by crystal growth.

As shown in FIG. 9C, the first layer region 21r is formed on the first crystal region 11c. For example, graphene (or graphite) that is used to form the first layer region 21r is grown. Thus, the forming of the first member 10M (step S111) includes forming the first member 10M including the first layer region 21r and the first crystal region 11c on the conductive first substrate 50s (referring to FIG. 9C). The first crystal region 11c is between the first substrate 50s and the first layer region 21r. The orientation from negative (−σ) toward positive (+σ) of the polarization of the first crystal region 11c has a component in the orientation (a Z2-direction) from the first substrate 50s toward the first crystal region 11c. The first layer region 21r includes the first layer-shaped portion 21p. The first layer-shaped portion 21p includes at least one selected from the group consisting of graphene and a transition metal dichalcogenide. The multiple first layer-shaped portions 21p may be provided.

As shown in FIG. 9D, the first conductive layer E1 is formed (step S117). The first crystal region 11c is between the first conductive layer E1 and the first layer region 21r. The first substrate 50s is between the first conductive layer E1 and the first crystal region 11c.

As shown in FIG. 9E, the first intermediate region 21a that includes the first element 31 is formed. In one example, for example, the first intermediate region 21a is formed between the multiple first layer-shaped portions 21p of the first layer region 21r. The first intermediate region 21a is formed between the first layer region 21r and the first crystal region 11c. For example, the forming of the first intermediate region 21a (the introduction of the first element 31) is performed by vapor deposition of the first element 31 at reduced pressure.

The second structure body SB2 is prepared separately. The second structure body SB2 may be formed by a method similar to the method for manufacturing the first structure body SB1.

In step S120 recited above (the causing to oppose), the first layer-shaped portion 21p is between the first crystal region 11c and the second structure body SB2 (referring to FIG. 1).

According to a manufacturing method such as that recited above, a power generation element can be manufactured in which the efficiency can be increased stably.

### Fourth Embodiment

FIG. 10A and FIG. 10B are schematic cross-sectional views showing a power generation module and a power generation device according to a fourth embodiment.

As shown in FIG. 10A, the power generation module 210 according to the embodiment includes the power generation element 110 according to the first embodiment (or the power generation element 120 according to the second embodiment). In the example, multiple power generation elements 110 are arranged on a substrate 110S. In the following description, the “power generation element 110” may be the “power generation element 120”.

As shown in FIG. 10B, the power generation device 310 according to the embodiment includes the power generation module 210 recited above. Multiple power generation modules 210 may be provided. In the example, the multiple power generation modules 210 are arranged on a substrate 210S.

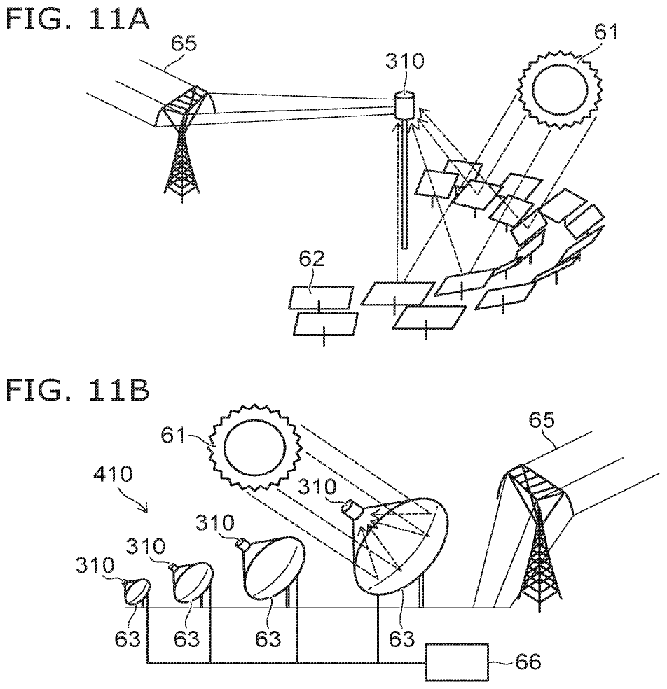

FIG. 11A and FIG. 11B are schematic views showing a power generation device and a power generation system according to the embodiment.

As shown in FIG. 11A and FIG. 11B, the power generation device 310 according to the embodiment (i.e., the power generation element 110 or the power generation module 210 according to the embodiment) is applicable to solar thermal power generation.

As shown in FIG. 11A, for example, the light from the sun 61 is reflected by a heliostat 62 and is incident on the power generation device 310 (the power generation element 110 or the power generation module 210). The light causes the first temperature T1 of the first conductive layer E1 and the first member 10M to increase. The first temperature T1 becomes higher than the second temperature T2. Heat is changed into current. The current is transmitted by a power line 65, etc.

As shown in FIG. 11B, for example, the light from the sun 61 is concentrated by a concentrating mirror 63 and is incident on the power generation device 310 (the power generation element 110 or the power generation module 210). The heat due to the light is changed into current. The current is transmitted by the power line 65, etc.

For example, the power generation system 410 includes the power generation device 310. In the example, multiple power generation devices 310 are provided. In the example, the power generation system 410 includes the power generation device 310 and a drive device 66. The drive device 66 causes the power generation device 310 to follow the movement of the sun 61. By following the movement of the sun 61, efficient power generation can be performed.

Highly efficient power generation can be performed by using the power generation element 110 (or the power generation element 120) according to the embodiment.

According to the embodiments, a power generation element, a power generation module, a power generation device, a power generation system, and a method for manufacturing a power generation element can be provided in which the efficiency can be increased stably.

In the specification, “nitride semiconductor” includes all compositions of semiconductors of the chemical formula BₓIn_{y}Al_{z}Ga_{1-x-y-z}N (0≤x≤1, 0≤y≤1, 0≤z≤1, and x+y+z≤1) for which the composition ratios x, y, and z are changed within the ranges respectively. “Nitride semiconductor” further includes Group V elements other than N (nitrogen) in the chemical formula recited above, various elements added to control various properties such as the conductivity type and the like, and various elements included unintentionally.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in power generation elements such as conductive layers, member crystal regions, layer regions, terminals, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all power generation elements, power generation modules, power generation devices, power generation systems, and methods for manufacturing power generation elements practicable by an appropriate design modification by one skilled in the art based on the power generation elements, the power generation modules, the power generation devices, the power generation systems, and the methods for manufacturing power generation elements described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A power generation element, comprising:
a first conductive layer;
a second conductive layer;
a first member provided between the first conductive layer and the second conductive layer, the first member including a first crystal region and a first layer region, the first crystal region being between the first layer region and the first conductive layer, an orientation from negative to positive of a polarization of the first crystal region having a component in a first orientation, the first orientation being from the first conductive layer toward the second conductive layer, the first layer region including a first layer-shaped portion spreading along a first surface, the first surface crossing the first orientation, the first layer-shaped portion including at least one selected from the group consisting of graphene and a transition metal dichalcogenide; and
a second member provided between the first member and the second conductive layer and separated from the first member.

2. The element according to claim 1, wherein
the first layer region includes a plurality of the first layer-shaped portions, and
one of the plurality of first layer-shaped portions is between the first crystal region and an other one of the plurality of first layer-shaped portions.

3. The element according to claim 2, wherein
the first member further includes a first intermediate region provided between the one of the plurality of first layer-shaped portions and the other one of the plurality of first layer-shaped portions, and
the first intermediate region includes at least one selected from the group consisting of Li, Na, K, Rb, Cs, Fr, Be, Mg, Ca, Sr, Ba, and Ra.

4. The element according to claim 1, wherein
the first member further includes a first intermediate region provided between the first layer region and the first crystal region, and
the first intermediate region includes at least one selected from the group consisting of Li, Na, K, Rb, Cs, Fr, Be, Mg, Ca, Sr, Ba, and Ra.

5. The element according to claim 3, wherein
the first layer-shaped portions includes graphene, and
the first intermediate region includes Cs.

6. The element according to claim 1, wherein a <000-1> direction of the first crystal region has a component in the first orientation.

7. The element according to claim 1, wherein the first crystal region has a wurtzite structure.

8. The element according to claim 1, wherein the first crystal region includes at least one selected from the group consisting of BaTiO₃, PbTiO₃, Pb(Zrₓ, Ti₁₋ₓ)O₃, KNbO₃, LiNbO₃, LiTaO₃, NaₓWO₃, Zn₂O₃, Ba₂NaNb₅O₅, Pb₂KNb₅O₁₅, and Li₂B₄O₇.

9. The element according to claim 1, wherein
the second member includes a second crystal region and a second layer region,
the second crystal region is between the second layer region and the second conductive layer,
an orientation from negative to positive of a polarization of the second crystal region has a component in a second orientation, the second orientation being from the second conductive layer toward the first conductive layer, and
the second layer region includes a second layer-shaped portion spreading along a second surface, the second surface crossing the second orientation, the second layer-shaped portion including at least one selected from the group consisting of graphene and a transition metal dichalcogenide.

10. The element according to claim 9, wherein
the second layer region includes a plurality of the second layer-shaped portions, and
one of the plurality of second layer-shaped portions is between the second crystal region and an other one of the plurality of second layer-shaped portions.

11. The element according to claim 10, wherein
the second member further includes a second intermediate region provided between the one of the plurality of second layer-shaped portions and the other one of the plurality of second layer-shaped portions, and
the second intermediate region includes at least one selected from the group consisting of Li, Na, K, Rb, Cs, Fr, Be, Mg, Ca, Sr, Ba, and Ra.

12. The element according to claim 9, wherein
the second member further includes a second intermediate region provided between the second layer region and the second crystal region, and
the second intermediate region includes at least one selected from the group consisting of Li, Na, K, Rb, Cs, Fr, Be, Mg, Ca, Sr, Ba, and Ra.

13. A power generation element, comprising:
a first conductive layer;
a second conductive layer;
a first member provided between the first conductive layer and the second conductive layer, the first member including a first crystal region, a first layer region, and a first intermediate region, the first crystal region being between the first layer region and the first conductive layer, an orientation from negative to positive of a polarization of the first crystal region having a component in a first orientation, the first orientation being from the first conductive layer toward the second conductive layer, the first intermediate region being provided between the first layer region and the first crystal region, the first intermediate region including at least one selected from the group consisting of Li, Na, K, Rb, Cs, Fr, Be, Mg, Ca, Sr, Ba, and Ra; and
a second member provided between the first member and the second conductive layer and separated from the first member.

14. The element according to claim 13, wherein
the first layer region includes a first layer-shaped portion spreading along a first surface, the first surface crossing the first orientation, and
the first layer-shaped portion includes at least one selected from the group consisting of graphene and a transition metal dichalcogenide.

15. A power generation module, comprising a plurality of the power generation elements according to claim 1.

16. A power generation device, comprising a plurality of the power generation modules according to claim 15.

17. A power generation system, comprising:
the power generation device according to claim 16; and
a drive device,
the drive device causing the power generation device to follow a movement of the sun.

18. A method for manufacturing a power generation element, comprising:
forming a first structure body; and
causing the first structure body and a second structure body to oppose each other and to be separated from each other,
the forming of the first structure body including
forming a first member on a first substrate, the first member including a first layer region and a first crystal region, the first layer region being between the first substrate and the first crystal region, an orientation from positive to negative of a polarization of the first crystal region having a component in an orientation from the first substrate toward the first crystal region, the first layer region including a first layer-shaped portion, the first layer-shaped portion including at least one selected from the group consisting of graphene and a transition metal dichalcogenide,
forming a first conductive layer on the first crystal region, and
removing the first substrate,
the first layer-shaped portion being between the first crystal region and the second structure body in the causing of the first structure body and the second structure body to oppose each other.

19. The method according to claim 18, wherein
the forming of the first member includes:
forming the first crystal region on the first substrate; and
forming the first layer region from a portion of the first substrate by performing heat treatment after the forming of the first crystal region.

20. A method for manufacturing a power generation element, comprising:
forming a first structure body; and
causing the first structure body and a second structure body to oppose each other and to be separated from each other,
the forming of the first structure body including
forming a first member on a first substrate, the first substrate being conductive, the first member including a first layer region and a first crystal region, the first crystal region being between the first substrate and the first layer region, an orientation from negative to positive of a polarization of the first crystal region having a component in an orientation from the first substrate toward the first crystal region, the first layer region including a first layer-shaped portion, the first layer-shaped portion including at least one selected from the group consisting of graphene and a transition metal dichalcogenide, and
forming a first conductive layer, the first crystal region being between the first conductive layer and the first layer region, the first substrate being between the first conductive layer and the first crystal region,
the first layer-shaped portion being between the first crystal region and the second structure body in the causing of the first structure body and the second structure body to oppose each other.
